(19) United States
(12) Patent Application Publication
(10) Pub. No.: US 2006/0189124 A1
(43) Pub. Date: Aug. 24, 2006

(54) Semiconductor device having a through contact through a housing composition and method for producing the same

(76) Inventors: Gottfried Beer, Nittendorf (DE); Jens Pohl, Bernhardswald (DE)

Correspondence Address: EDELL, SHAPIRO & FINNAN, LLC, 1901 RESEARCH BLVD., SUITE 400, ROCKVILLE, MD, 20850, US

(21) Appl. No.: 11/350,287

(22) Filed: Feb. 9, 2006

(30) Foreign Application Priority Data
Feb. 10, 2005 (DE) 10 2005 006 280.6

(51) Int. Cl. H01L 21/4763; H01L 23/48

(52) U.S. Cl. 438/622; 257/774

(57) ABSTRACT

A semiconductor device includes a housing composition and a through contact extending through the housing composition. The through contact is provided in a contact hole formed through the housing composition and having an asymmetrical funnel form with at least two opposite inner wall sides oriented substantially perpendicular to the top side of the housing and a further inner wall side inclined in such a way that the contact hole has an elongated-hole cross section at the top side of the housing. In the region of the contact pad, the contact hole has a cross section adapted to the contact pad. The through contact includes a contact-making conductor track that extends from the top side of the housing along the inclined fourth inner wall side to the contact pad.

### CROSS REFERENCE TO RELATED APPLICATIONS

This application claims priority under 35 USC §119 to German Application No. DE 10 2005 006 280.9, filed on Feb. 10, 2005, and titled “Semiconductor Device Having a Through Contract Through a Housing Composition and Method for Producing the Same,” the entire contents of which are hereby incorporated by reference.

### FIELD OF THE INVENTION

The invention relates to a semiconductor device having a through contact through a housing composition of the semiconductor device to contact pads within the semiconductor device, the through contact being arranged in a contact hole through the housing composition.

### BACKGROUND

German Patent Application No. DE 10 2004 027 094.5 discloses a contact hole incorporated into a housing composition; however, this contact hole has no through contact whatsoever, but rather serves to uncover a sensor region of a semiconductor sensor chip in a housing in order to enable the sensor function after the sensor chip has been embedded in the housing composition.

In addition, techniques such as laser ablation are known, in which contact holes to contact areas are introduced into a housing composition. However, such techniques have the disadvantage that the geometry of the contact holes produced in this way is typically embodied in cylindrical fashion or in conical fashion with a diameter that increases toward the top side of the housing of the semiconductor device.

Such a geometry influences the further production steps. Thus, in the case of cylindrical contact holes, the problem occurs that the steep vertical side walls cannot be provided with a metallization, or can be provided with a metallization only to an inadequate extent, so that vertical through contacts of the order of magnitude of the contact pads with which contact is to be made, within the housing composition, cannot be realized reliably in terms of production engineering. In the case of conical or funnel-shaped holes, it is possible, depending on the formation of the angle of the inner lateral surfaces, to achieve an improved metallization of the side walls, but these require a larger area due to the conical passage openings on the top side of the semiconductor device, so that the pitch of the contact pads arranged in the housing composition cannot always be complied with.

### SUMMARY OF THE INVENTION

The present invention provides a semiconductor device which produces electrically conductive connections between two planes of a semiconductor housing in such a way that the top side of the semiconductor housing has a new contact plane which corresponds to the lower contact plane within the housing that has contact pads of a wiring substrate. In present large scale integrated semiconductor circuits, the requisite number of contacts in the planes to be connected by through contact is typically 60 to 200 required through contacts.

In accordance with the present invention, a semiconductor device includes a through contact through a housing composition of the semiconductor device to contact pads within the semiconductor device. The through contact is arranged in a contact hole through the housing composition of the semiconductor device. The contact hole has an asymmetrical funnel form with at least two opposite inner wall sides oriented virtually perpendicular to the top side of the housing and at least one further inner wall side inclined in such a way that the contact hole has, at the top side of the housing, an elongated-hole cross section and, in the region of the contact pads, a cross section adapted to the contact pad. A contact-making conductor track, which forms the through contact, extends from the top side of the housing along the inclined further inner wall side as far as the contact pad.

The semiconductor device of the invention has the advantage that a reliable connection is created via the contact-making conductor track from the top side of the housing to the contact pad, especially since, as mentioned above, only three inner wall sides are formed approximately in perpendicular fashion and thus in part cannot be coated, but at least one fourth inner wall side is formed in inclined fashion, on which a through contact via a conductor track extending from the top side as far as the contact pads is present with high reliability.

Furthermore, the semiconductor device has the advantage that the pitch provided within the housing can also be maintained on the top side of the housing since an extra area requirement arises only in one direction, namely in the longitudinal extent of the elongated-hole cross section of the contact hole, but not in the pitch since the three remaining inner wall sides are embodied perpendicular to the top side of the housing and, consequently, it is possible to adapt the pitch of the contact pads within the semiconductor device without an additional area requirement.

Preferably, the semiconductor device includes, on its top side, a multiplicity of through contacts which are arranged at least in one row and are oriented in such a way that the elongated-hole cross section is situated transversely or obliquely with respect to the orientation of the row. This embodiment of the invention has the advantage that a multiplicity of contact pads arranged in at least one row within the semiconductor device are also available on the top side of the semiconductor device and can be contact-connected via the corresponding contact-making conductor track to the contact pads within the semiconductor device.

If a plurality of rows are arranged annularly with contact pads arranged next to one another in the semiconductor device, then this arrangement can be maintained on the top side as well with the aid of the through contacts according to the invention. If the contact pad rows are arranged parallel to one another within the housing, then it is merely necessary to take account of the fact that the distance between the rows is large enough to configure the elongated holes on the top side of the semiconductor device such that the contact-making conductor tracks from the top side of the semiconductor device over the inclined inner wall side of the contact hole to the contact pads do not touch one another on the top side of the semiconductor device.

In a further embodiment of the invention, the conductor track includes at least two metal layers, with a lower first layer made of a seed layer a few nanometers thick (e.g., no greater than about 5 nanometers thick). Applying such a seed layer a few nanometers thick as a first layer has the advantage that the entire top side of the semiconductor device can be metallized and all the contact holes can thus be provided with a seed layer, so that they are firstly coupled electrically for example for an electrochemical deposition and, consequently, a corresponding potential for all the contact-making conductor tracks to be deposited can be applied to the seed layer. Furthermore, the seed layer that is a few nanometers thick has the advantage of enabling an intensive adhesion or meshing with the housing composition given a suitable choice of the deposited material.

In a further embodiment of the invention, the conductor track includes a second metal layer in the form of a conductor track layer hundreds of nanometers thick. This conductor track layer provides the actual low-impedance connection between the top side of the semiconductor device and the contact pads in the semiconductor device. It can be applied selectively both in an additive method and in a subtractive method, for which purpose corresponding photolithographic masks are used or a patterning of the contact-making conductor tracks is achieved by a printing jet technique.

Finally, in a further embodiment of the invention, it is possible for the conductor track to have an upper metal layer which fills the entire contact hole. In order to fill the entire contact hole, either a chemical or an electrochemical deposition is used or, once again by targeted printing jet techniques, the contact holes can be filled with their conductor track seed layer comprising a corresponding metal that conducts in low-impedance fashion, such as copper or a copper alloy.

Preferably, the conductor track, on the top side of the housing, merges into a conductor track lug forming a housing external contact area. Such conductor track lugs as housing external contact areas are advantageous when the semiconductor device is to be used as the base device of a stack. For test purposes, too, it is advantageous to provide, on the top side of the housing, housing external contact areas by which specific contact pads in the semiconductor device housing can be contact-connected externally for said test purposes.

In a further embodiment of the invention, a plurality of conductor track lugs of the through contacts are positioned in such a way that they correspond in position and arrangement to a position and arrangement of external contacts of a semiconductor device to be stacked. In this embodiment, the offset of the conductor track lugs with respect to the contact pads within the semiconductor device on account of the inclined conductor track and the elongated hole arising on the top side as a result of the asymmetrical funnel form can be combated by the contact pads within the semiconductor device having a wiring structure whose structure takes account of said offset.

The conductor track lugs of the through contacts may also be positioned in such a way that they correspond in position and arrangement to a position and arrangement of external contacts on the underside of the semiconductor device. In this case, too, on the circuit plane of the contact pads within the semiconductor device, a wiring structure will ensure that the lateral offset of the conductor track lugs with respect to the contact pads is compensated for in order to ensure an exact orientation between the external contacts on the underside of the semiconductor device and the housing external contact areas formed by the conductor track lugs on the top side of the semiconductor device.

A further embodiment of the invention provides for the fourth inner wall side of the contact hole to have a stepped form. Such a stepped form may, on the one hand, improve the fixing of the metallic conductor track or the metallic seed layer on the plastic housing composition, because the adhesion area is enlarged compared with a smooth inclined fourth inner side wall; on the other hand, it may also be advantageous from a method engineering standpoint for the inclined inner wall side to have a stepped form, especially since this enables the contact hole to be introduced layer by layer into the housing composition in terms of production engineering.

In a further preferred embodiment, the housing composition comprises a polymeric plastic, preferably an epoxy resin. The laser scanning technique, as is known from the patent application DE 10 2004 027 094, has proved to be worthwhile in such plastic housing compositions. For housing compositions made of ceramic material, the ceramic material may comprise a sintering ceramic based on aluminum oxide, and the laser removal method is one of the few possibilities for still processing such hard and brittle materials after completion of the housing and for introducing corresponding contact holes.

The semiconductor devices according to the invention are preferably used as base semiconductor devices of a semiconductor device stack. In particular, it is then advantageous if the conductor track lugs as housing external contacts on the top side and the external contacts on the underside are completely identical in terms of their arrangement and position. On the other hand, it is also possible to configure the conductor track lugs as upper housing external contacts in such a way that corresponding discrete components with surface-mountable electrodes can be arranged on the semiconductor device.

A method for producing a semiconductor device including a through contact through a housing composition of the semiconductor device to contact pads within the semiconductor device comprises the following method steps. First, the housing composition is removed layer by layer or continuously, the removal width per removal layer remaining constant and the removal length being reduced layer by layer or continuously with increasing removal depth.

For a layer by layer removal, said removal length is reduced in intervals; and for a continuous removal, said removal length is shortened continuously. This shortening of the removal length is configured in such a way that a contact hole with an asymmetrical funnel form is formed, which has three inner sides oriented virtually perpendicular to the top side of the housing and a fourth inner wall side inclined in such a way that the contact hole, at the top side of the housing, forms an elongated-hole cross section and, in the region of the contact pad, is adapted to the size of the contact pad. After such a contact hole has been incorporated through the housing composition, a seed layer made of metal a few nanometers thick (e.g., no greater than about 5 nanometers thick) may be deposited over a large area on the top side of the semiconductor device and in particular along the inclined inner wall side of the contact hole. Said seed layer is subsequently reinforced selectively to form a conductor track from the top side of the housing over the inclined inner wall side as far as the contact pad within the semiconductor device.

This method has the advantage that subsequently, that is to say after the housing composition has been applied to the components of a semiconductor device, it is possible to form accesses to the contact pads in such a way that contact-making conductor tracks, in space-saving fashion, can be connected to inner contact pads of a semiconductor device. This method furthermore has the following advantages:
1. Yielding a space-saving embodiment, that is to say that more contact holes can be accommodated on a smaller area than previously. This is particularly advantageous in the case of housings for mobile applications, for example in the case of mobile telephones.
2. By virtue of the slotted embodiment of the asymmetrical funnel form, webs remain between the contact holes, on which webs additional conductor tracks can be laid or deposited in order, for example, to make contact with a second or even third row of through contacts in corresponding contact holes.
3. This method achieves a process reliability which has hitherto been possible only in the case of electrical through contacts through a housing with corresponding symmetrical funnel forms of the contact holes and hence spatially extensive holes.
4. During the introduction of the housing contact holes, less housing composition has to be removed, which means shorter process times and a lower thermal loading for the housing. Consequently, this production method can provide 3D contacts via the inclined fourth inner side wall for semiconductor devices. Consequently, it is possible to realize a high number of housing external contact areas on the top side of the semiconductor chip in space-saving fashion.

In one preferred exemplary embodiment of the method according to the invention, the removal width for the contact hole is adapted to the width of the contact pad. This need not mean that a square contact pad is then completely uncovered through the contact hole. Rather, it suffices if, by way of example, it becomes possible to effect a circular contact-connection of the contact pad through the contact hole via the through contact which is then provided. It is also advantageous if the edges of the contact pad are not completely uncovered during the introduction of the contact hole, but rather remain in the protective housing composition.

Furthermore, a method is preferred in which the removal length for the contact hole is introduced transversely with respect to the orientation of a through contact row on the top side of the housing. This form of implementation of the method fully exhausts the positive aspects afforded by the contact hole configuration according to the invention, because a minimized pitch of identical magnitude which is predefined by the contact pads within the semiconductor device can thereby also remain for the housing external connections on the top side of the semiconductor device.

Preferred methods for producing the asymmetrical funnel form as a contact hole are a laser removal method, a plasma etching method, and/or a directed plasma beam method. The directed methods have the advantage that the plasma etching beam or the laser beam can be scanned in order to introduce the elongated-hole geometry on the top side of the semiconductor device for the contact hole with a symmetrical funnel form. In a further embodiment of the invention, preferably, first a vertical contact hole is introduced by a vertical removal beam, and then the inclined inner wall side is beveled by an inclined removal beam. For this purpose, either two beam apparatuses can produce the contact hole from different angles, or an individual beam source is pivoted by the angle of inclination of the fourth inclined inner wall side. The last method variant may involve providing a pivoting of the semiconductor device or a pivoting of a beam source or a use of two beam sources with different removal angles, in order to reduce the elongated-hole cross section continuously, while a stepped introduction of the inclined inner wall side by the removal beam arises during scanning by a shorter removal length being scanned in the longitudinal direction layer by layer toward the depth.

The above and still further objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 depicts a partial view in perspective of a semiconductor device of a first embodiment in accordance with the present invention.

FIGS. 2 to 7 depict a series of partial views showing the method steps of forming the semiconductor device of FIG. 1 in accordance with the present invention, where FIG. 2 shows a cross-section through a partial region of the semiconductor device in the vicinity of a contact pad, FIG. 3 shows a cross-section through the partial region of FIG. 2 after the introduction of a contact hole, FIG. 4 shows a perspective view of the partial region of FIG. 3, FIG. 5 shows a cross-section through a contact hole with stepped formation of an inclined fourth inner wall side of the contact hole, FIG. 6 shows a cross-section through the partial region of FIG. 3 after the application of a seed layer in the region of the contact hole, and FIG. 7 shows a cross-section through the partial region of FIG. 6 after the reinforcement of the seed layer by a patterned conductor track layer and etching-back or stripping of the seed layer.

FIG. 8 depicts a plan view of a detail from a contact hole row on the top side of a semiconductor device in accordance with the present invention.

FIG. 9 depicts a cross-section through the contact hole row along the sectional plane B-B shown in FIG. 8.

FIG. 10 depicts a cross-section through the contact hole row along the sectional plane A-A shown in FIG. 8

FIG. 11 depicts a cross-section through a semiconductor base device in accordance with a second embodiment of the present invention.

FIG. 12 depicts a cross-section through a semiconductor device stack in accordance with a third embodiment of the present invention.

### DETAILED DESCRIPTION

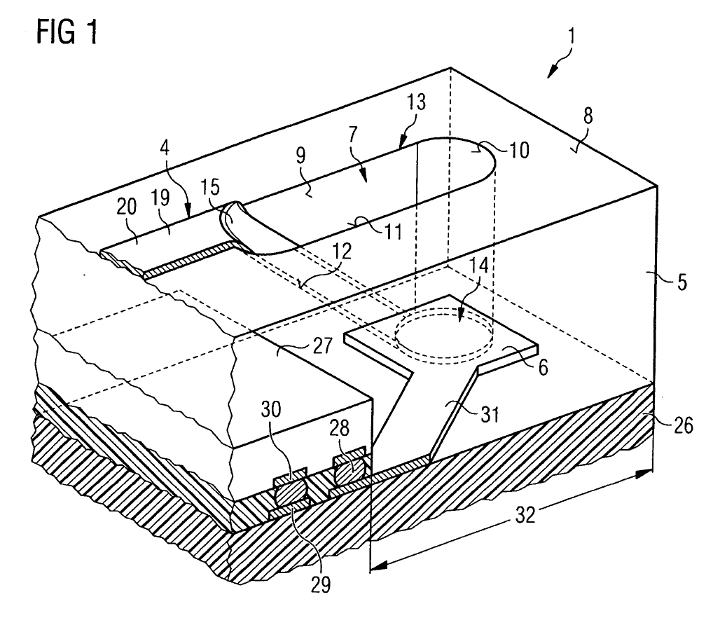

FIG. 1 shows a perspective partial view of a semiconductor device 1 of a first embodiment of the invention. The semiconductor device 1 includes a semiconductor chip 27 arranged by contact areas 30 and flip-chip contacts 28 with flip-chip contact pads 29 on a wiring substrate 26. The wiring substrate 26 includes a wiring structure 31 which connects the flip-chip contact pads 29 to corresponding contact pads 6 in the edge region 32 of the wiring substrate 26. The semiconductor chip 27, the wiring structure 31 and the contact pad 6 are embedded in a housing composition 5.

The housing composition 5 is illustrated in transparent fashion in this illustration in order to better elucidate the invention. Such a housing composition 5 often has a nontransparent polymeric plastic composition, which is typically filled with SiO₂ filler, or a nontransparent ceramic composition based on aluminum dioxide. From the top side 8 of the housing, a contact hole 7 is introduced into the housing composition 5, said contact hole including three inner wall sides 9, 10 and 11 which are introduced into the housing composition 5 substantially perpendicular to the top side 8 of the housing and which reach as far as the top side of the contact pad 6. A fourth inner wall side 12 of the contact hole 7 is inclined toward the top side 8 and leads obliquely toward the contact pad 6. Said inclined inner wall side 12 carries a through contact 4 in the form of a conductor track 15 reaching from the top side 8 as far as the contact pad 6. On the top side 8, the conductor track 15 forms a conductor track lug 19 serving as a housing external contact area 20 on the top side 8.

Lower external contacts (not shown in FIG. 1) of such a semiconductor device 1 may be arranged on the underside of the wiring substrate 26 currently in a number of between 60 and 1000 external contacts. Each individual one of these external contacts (not shown) is connected via through contacts (not shown) in the wiring substrate 26 and via the wiring structure 31 to the contact pads 6. The passage opening 7 includes, on the top side 8 of the semiconductor device 1, an elongated-hole cross section 13 and, in the region of the contact pad 6 within the semiconductor 1, a cross section 14 which is adapted to the contact pad 6 in its areal extent at the bottom of the contact hole 7. In this context, “adapted” is understood to mean that the cross section 14 at the bottom of the contact hole is less than or equal to (i.e., no greater than) the area of the area of the contact pad in terms of areal extent, so that the edges of the contact pad 6 remain embedded in the housing composition 5 of the semiconductor device 1.

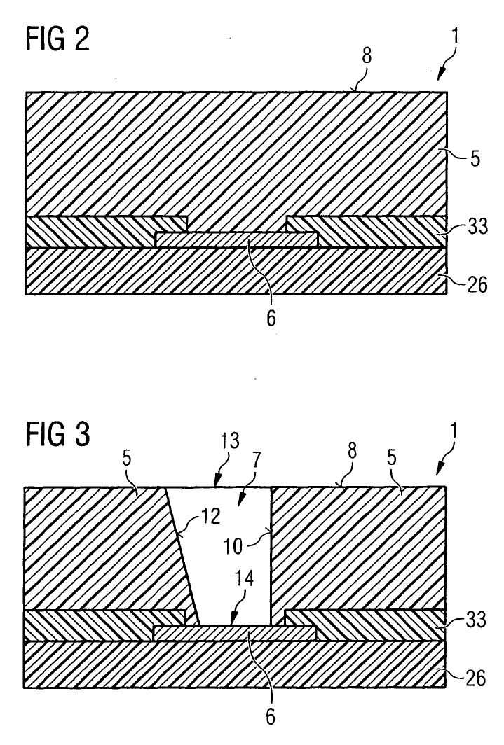

FIGS. 2 to 7 show the diagrams of individual production steps of a method for producing the semiconductor device 1 of FIG. 1. Components having functions identical to those in FIG. 1 are identified by the same reference symbols in FIGS. 2 to 7 and are not discussed separately.

FIG. 2 shows a cross section through a partial region of the semiconductor device 1 according to FIG. 1 in the vicinity of a contact pad 6. The housing composition 5 extends above the contact pad 6 and, with its top side 8, simultaneously forms the top side of the semiconductor device 1. A dielectric layer 33 is additionally arranged on the wiring substrate 26, the contact pad 6 being partly kept free of the adhesion promoting layer 33 on its top side.

FIG. 3 shows a cross section through the partial region of FIG. 2 after the introduction of a contact hole 7. The contact hole 7 has an elongated-hole cross section 13 at the top side 8. In the bottom region, the cross section 14 of the contact hole 7 is adapted to the top side of the contact pad 6 that is kept free of the adhesion promoting layer 33. While one inner wall side 10 of the contact hole 7 is introduced into the housing composition 5 virtually at right angles to the top side 8 of the semiconductor device 1, the inner wall side 12 is arranged in a manner inclined with respect to the top side 8, so that an elongated-hole cross section 13 arises at the top side 8 and the cross section 14 at the bottom of the contact hole 7 is about circular.

FIG. 4 shows a perspective view of the partial region of FIG. 3. The housing composition 5 is again illustrated in transparent fashion in order to visualize the resulting contact hole 7 and a geometry in the housing composition 5. At the top side 8, first of all the elongated-hole cross section 13 having a length l can be seen, which cross section arose during the introduction of the contact hole. In the bottom region, the cross section 14 of the contact hole is circular with a diameter which corresponds to the width b of the elongated-hole cross section 13, and is adapted to the areal extent of the contact pad 6 of the semiconductor device 1. While three inner wall sides 9, 10 and 11 are introduced into the housing composition 5 virtually perpendicular to the top side 8, the inner wall side 12 runs at an angle of inclination in the direction toward the bottom region of the contact hole 7.

FIG. 5 shows a cross section through a contact hole 7 with stepped formation of the inclined fourth inner wall side 12 of the contact hole 7. Such a stepped form 25 for the inclined fourth inner side wall 12 arises as a result of layer by layer removal of the housing composition 5, this form of implementation of the method having made use of a laser removal method in which the width of the removal at the top side 8 is adapted to the width of the contact pad 6, while the length l per removal layer is reduced with increasing depth t. In this case, the stepped form runs to a virtually oblique or inclined ramp. The advantages of this embodiment of the invention have already been explained above. Any beam removal method, such as a laser beam removal technique or a plasma beam removal technique or else an electron beam removal technique, can be used as layer by layer removal of the removal layers 34 to 40. Etching techniques are also conceivable, but they have the disadvantage that a new photoresist mask has to be applied in each intermediate step in order to realize the gradual shortening of the length l with increasing depth t, as shown in FIG. 5.

FIG. 6 shows a cross section through the partial region of FIG. 3 after the application of a seed layer 17 in the region of the contact hole 7. As shown in FIG. 6, the entire top side 8 of the semiconductor device may be provided with a thin seed layer a few nanometers thick (e.g., no greater than about 5 nanometers thick), which may be applied by a sputtering technique, physical vapor deposition or chemical vapor deposition. The inner wall side 10 arranged perpendicular to the top side 8 and also the inner wall sides 9 and 11 (not shown here) are provided with a seed layer to a slight extent through to not at all, particularly if a sputtering technique or vapor deposition technique is used during which metal atoms preferably impinge rectilinearly on the top sides to be coated. However, this gives rise to a seed layer to which, for example, an electrical potential can be applied in order subsequently to reinforce the seed layer by an electrochemical deposition.

FIG. 7 shows a cross section through the partial region of FIG. 6 after the reinforcement of the seed layer 17 by a patterned conductor track layer 18 and etching-back of the seed layer. The patterning may be achieved by additive or subtractive application techniques, the conductor track layer being limited during patterning to a conductor track lug 19 on the top side of the semiconductor device 8 and to a conductor track layer along the inner wall side and to a reinforcement at the bottom of the contact hole 7.

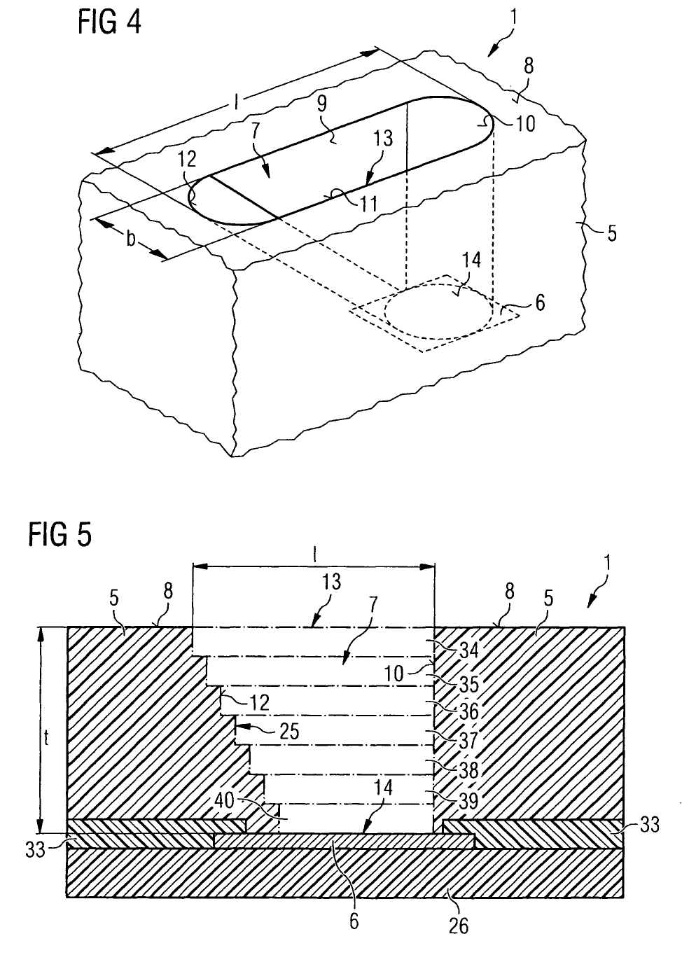

FIG. 8 shows a plan view of a detail from a contact hole row 16 on the top side 8 of a semiconductor base device 2. In this case, the contact areas 6 are oriented in a line 41 and the contact holes 7 are arranged with their length I perpendicular to said line 41. Other arrangements, e.g. offset on two sides or arranged in smaller groups, are also possible. It thereby becomes possible for a high number of passage openings 7 to be arranged in a row 16 and additionally for webs made of housing composition 5 to remain between the contact holes 7, on which webs top side conductor tracks can be led. During the introduction of the elongated-hole row, either the semiconductor device can be pivoted about the line 41, in order to introduce the inclined inner wall side 12, or a removal beam can be correspondingly pivoted by the angle of inclination. On the other hand, it is also possible, as already outlined above, to realize the inclined inner wall side 12 in removal steps whilst reducing the length l with increasing depth t of the elongated hole 7.

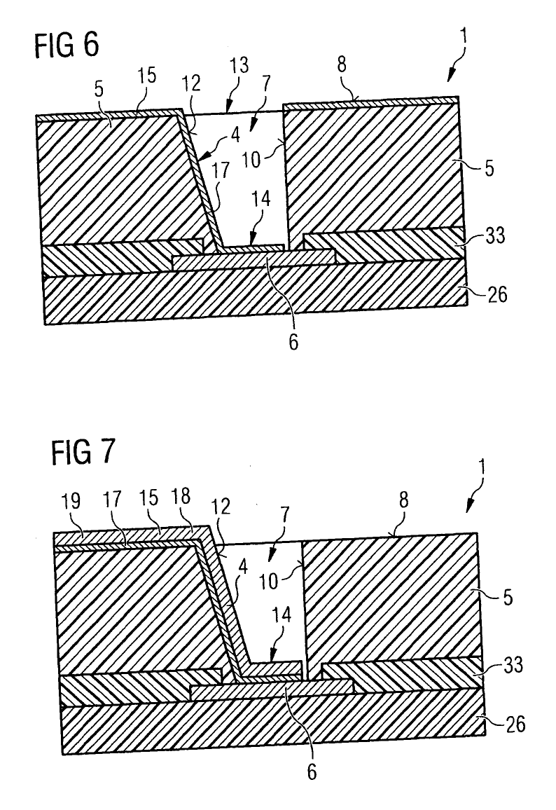

FIG. 9 shows a cross section through the contact hole row 16 along the sectional plane B-B from FIG. 8. This view reveals the inner wall sides 9 and 11 which are introduced into the housing composition 5 substantially perpendicular to the top side 8 and reach as far as the contact pad 6 on the wiring substrate 26.

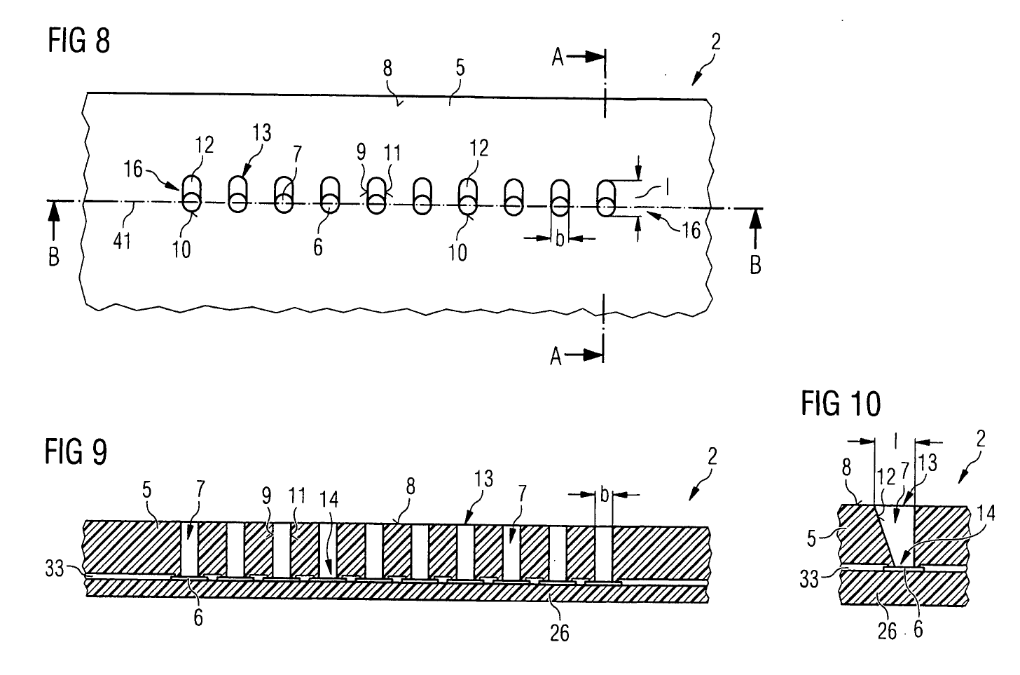

FIG. 10 shows a cross section through the contact hole row 16 along the sectional plane A-A from FIG. 8. This cross section of FIG. 10 corresponds to the cross section of FIG. 3 in the context of the discussion of the production method, so that the individual reference symbols and the individual features of this contact hole 7 will not be discussed in detail again.

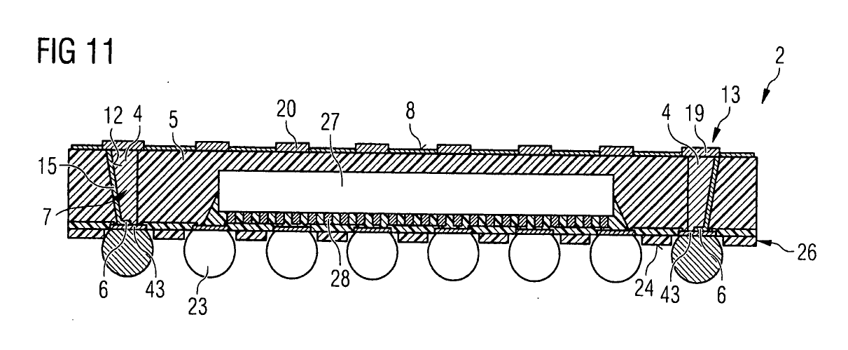

FIG. 11 shows a cross section through a semiconductor base device 2 in accordance with a second embodiment of the invention. This semiconductor base device 2 is formed using the technique and the design shown in FIGS. 8 to 10 in order to realize an identical arrangement and size of the external contact areas 43 and 20 both on the underside 24 of the semiconductor base device 2 and on the top side 8 of the semiconductor base device 2, respectively, by providing through contacts 4 through the housing composition 5 in an asymmetrical funnel form, as discussed in detail above. In principle, however, the arrangement of the housing external contacts 20 on the top side 8 of the semiconductor device is independent of the arrangement of the external contacts 23 on the underside 24 of the semiconductor device. In the case of this base device, the semiconductor chip 27 is arranged with flip-chip contacts 28 on a wiring substrate 26, which simultaneously carries the external contacts 23.

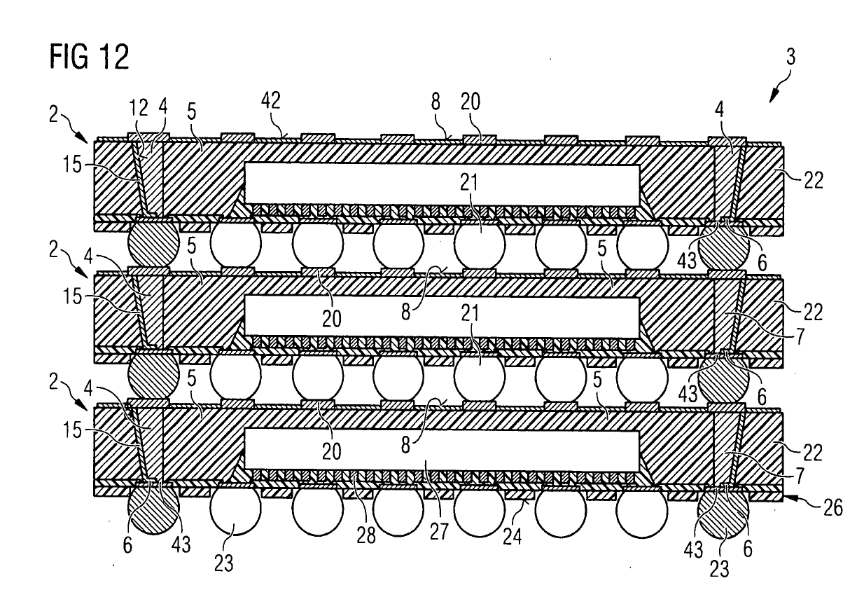

FIG. 12 shows a cross section through a semiconductor device stack 3 in accordance with a third embodiment of the invention. The semiconductor device stack 3 is assembled, for example, from three identical semiconductor base devices 2 one on top of another. However, it also holds true in this embodiment that the top side 42 of the semiconductor device stack or the top side 8 of the topmost semiconductor device 2 may have external contact areas 20 arranged in arbitrary fashion. The stacked semiconductor devices 22 include, on their undersides, external contacts 21 which correspond in size and arrangement to the size and arrangement of the housing external contacts 20 of the semiconductor devices arranged underneath in the semiconductor device stack 3. It is likewise possible for the bottommost semiconductor device of said device stack 3, which is called the semiconductor base device 2, to have an independently arranged number of external contacts 23 on the underside 24. Accordingly, a large range of applications can be covered with the embodiment of through contacts 4 according to the invention.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE SYMBOLS

1 Semiconductor device
2 Semiconductor base device
3 Semiconductor stack
4 Through contact
5 Housing composition
6 Contact pad
7 Contact hole
8 Top side of the housing or of the semiconductor device
9 First inner wall side
10 Second inner wall side
11 Third inner wall side
12 Fourth inner wall side
13 Elongated-hole cross section
14 Cross section at the bottom of the contact hole
15 Conductor track
16 Row or contact hole row
17 First metal layer or seed layer
18 Second metal layer or conductor track layer
19 Conductor track lug
20 Housing external contact area
21 External contact of the semiconductor device to be stacked
22 Semiconductor device to be stacked
23 External contact on the underside
24 Underside of the semiconductor device
25 Stepped form
26 Wiring substrate
27 Semiconductor chip
28 Flip-chip contact
29 Flip-chip contact pad
30 Contact area of the semiconductor chip
31 Wiring structure
32 Edge region
33 Dielectric
34-40 Removal layer
41 Line
42 Top side of the semiconductor device
43 External contact area on the underside
b Removal width
l Removal length
t Removal depth

What is claimed:

1. A semiconductor device comprising:
a housing composition including a top side and a bottom side;
a contact pad disposed within the semiconductor device; and
a through contact extending through the housing composition from the top side to the contact pad;
wherein the through contact is arranged in a contact hole formed in the housing composition, the contact hole having an asymmetrical funnel shape with at least two opposite inner wall sides oriented substantially perpendicular to the top side of the housing composition and at least one further inner wall side that is inclined as the further inner wall side extends from the top side of the housing composition to the contact pad such that the contact hole has an elongated cross-section at the top side of the housing composition and a cross-section in the region of the contact pad that is no greater than the areal extent of the contact pad; and
wherein the through contact comprises a contact-making conductor track that extends from the top side of the housing along the inclined further inner wall side to the contact pad.

2. The semiconductor device of claim 1, further comprising a plurality of through contacts extending through contact holes from the top side of the housing composition to corresponding contact pads disposed within the semiconductor device so as to engage the corresponding contact pads, wherein the through contacts are arranged in at least one row and are oriented in a manner such that the elongated cross section of each contact hole at the top side of the housing is aligned transverse to the orientation of the at least one row of through contacts.

3. The semiconductor device of claim 1, wherein the conductor track comprises at least two metal layers including a lower first layer consisting essentially of a seed layer having a thickness of no greater than about 5 nanometers.

4. The semiconductor device of claim 3, wherein the conductor track further includes a second metal layer having a thickness of at least about 100 nanometers.

5. The semiconductor device of claim 1, wherein the conductor track comprises a metal layer that fills the contact hole.

6. The semiconductor device of claim 1, wherein the conductor track merges into a conductor track lug on the top side of the housing composition to form an upper housing external contact area.

7. The semiconductor device of claim 1, further comprising a plurality of through contacts extending through contact holes from the top side of the housing composition to corresponding contact pads disposed within the semiconductor device so as to engage the corresponding contact pads, and each conductor track merges into a corresponding conductor track lug on the top side of the housing composition to form an upper housing external contact area, wherein the conductor track lugs are aligned to facilitate stacking of a second semiconductor device on the top surface of the housing composition such that the conductor track lugs correspond and engage with external contacts disposed on a surface of the second semiconductor device.

8. The semiconductor device of claim 1, further comprising a plurality of through contacts extending through contact holes from the top side of the housing composition to corresponding contact pads disposed within the semiconductor device so as to engage the corresponding contact pads, and each conductor track merges into a corresponding conductor track lug on the top side of the housing composition to form an upper housing external contact area, wherein the conductor track lugs are aligned to correspond in position and arrangement to a position and arrangement of external contacts disposed on an underside of the semiconductor device.

9. The semiconductor device of claim 1, wherein the further inner wall side of the contact hole includes a stepped profile.

10. The semiconductor device of claim 1, wherein the housing composition comprises a polymeric plastic.

11. The semiconductor device of claim 1, wherein the housing composition comprises an epoxy resin.

12. The semiconductor device of claim 1, wherein the housing composition comprises a ceramic material.

13. The semiconductor device of claim 1, wherein the housing composition comprises an aluminum oxide-based sintering ceramic.

14. A component comprising a plurality of semiconductor devices with each semiconductor device having a configuration as described in claim 1, wherein the semiconductor devices are arranged in a stacked manner with respect to each other.

15. A method for producing a semiconductor device including a through contact extending through a housing composition of the semiconductor device to contact pads within the semiconductor device, the method comprising:
consecutively removing layers of a selected thickness and selected length and width dimensions from the housing composition and beginning at a top side of the housing composition to form a contact hole extending through the housing composition from the top side of the housing composition to a contact pad disposed within the semiconductor device, wherein the width dimension of each removed layer is substantially constant while the length dimension is reduced as each consecutive layer is removed and as the contact hole increases in depth from the top side of the housing composition such that the contact hole that is formed has an asymmetrical funnel shape and includes at least two opposite inner wall sides that are oriented substantially perpendicular to the top side of the housing composition and at least one further inner wall side that is inclined as the further inner wall side extends from the top side of the housing composition to the contact pad such that the contact hole has an elongated cross-section at the top side of the housing composition and a cross-section in the region of the contact pad that is no greater than the areal extent of the contact pad;
applying a seed layer of metal having a thickness of no greater than about 5 nanometers thick along the inclined inner wall side (12) of the contact hole (7),
selectively reinforcing the seed layer to form a conductor track extending from the top side of the housing composition and over the further inner wall side to the contact pad.

16. The method of claim 15, wherein the width of the contact hole is about the same width as the contact pad.

17. The method of claim 15, wherein a plurality of contact holes are formed from the top side of the housing composition to a plurality of contact pads disposed within the semiconductor device, the contact holes are arranged in a row along the top side of the housing composition, and the length of each contact hole is transverse the orientation of the row of contact holes.

18. The method of claim 17, wherein the semiconductor device is pivoted about a pivot axis along the orientation of the row during the formation of the contact holes by consecutive removal of layers of the housing composition.

19. The method of claim 15, wherein the consecutive removal of layers from the housing composition to form the contact hole is achieved via a laser removal process.

20. The method of claim 19, wherein the contact hole is formed by first forming a vertical contact hole within the housing composition via a vertical laser removal beam and the further inner wall side is then formed by beveling one side of the vertical contact hole using an inclined laser removal beam.

21. The method of claim 15, wherein the consecutive removal of layers from the housing composition to form the contact hole is achieved via a plasma etching process.

22. The method of claim 21, wherein the consecutive removal of layers from the housing composition to form the contact hole is achieved using a directed plasma etching beam.
